(19) United States
(12) Patent Application Publication
(10) Pub. No.: US 2015/0016051 A1
(43) Pub. Date: Jan. 15, 2015

(54) DISPLAY ASSEMBLY HAVING GRADUATED MAGNETIC FASTENING CHARACTERISTICS

(71) Applicant: Toshiba Global Commerce Solutions Holdings Corporation, Tokyo (JP)

(72) Inventors: Dean F. Herring, Youngsville, NC (US); Brad M. Johnson, Raleigh, NC (US); Jeffrey J. Smith, Raleigh, NC (US); Robert A. Myers, Cary, NC (US)

(21) Appl. No.: 13/942,629

(22) Filed: Jul. 15, 2013

(51) Int. Cl. H05K 5/02; G06F 1/16

(52) U.S. Cl. CPC H05K 5/0217; G06F 1/1633; G06F 1/1632
USPC 361/679.43; 361/679.01; 361/679.55

(57) ABSTRACT

A display assembly is provided. The display may include a holder defining a first portion and an electronic device defining a corresponding second portion that is in magnetic attraction to the first portion when the electronic device is positioned about the holder. At least one of the first portion and the second portion defines a magnet having an exposed magnetic surface area that increases along a length of the magnet.

### BACKGROUND

1. Field of the Invention

The present invention relates to a display assembly having graduated magnetic engaging characteristics. The display assembly may be used for engaging an electronic device with a holder or display stand and may be advantageously provided with the graduated engaging characteristics in order to provide for enhanced engaged of the electronic device about the holder or display stand.

2. Description of Related Art

Display assemblies are used for displaying or providing ease of access to an electronic device. The display assembly may provide power or input and output communications with the electronic device. Alternatively, the display assembly may be provided only for securing the electronic device in a position that is convenient for a user or for display. The display assembly may include a cradle, docking station, or other structure that is configured for receiving the electronic device.

The electronic device may be engageably received within the cradle or docking station by any of a number of manners. For example, a hooking or locking mechanism may be employed where a hook or lock selectively engages the electronic device. In this manner, the cost to produce the device can be prohibitive. Additionally, an increased numbers of components can lead to product failure.

A magnet assembly may be used for engaging an electronic device with a support or holder, however, magnet assemblies may be undesirable if the magnetic force is greater than a desired amount and pulls a device towards the holder when not desired by an operator. In this instance, a smaller magnetic force is desired, however, the force must also remain sufficiently strong so that the electronic device remains secure within the holder when the electronic device is supposed to be in the docked position.

Accordingly, there is a need for a display assembly having a desired and advantageously provided magnetic attraction force compared to conventional devices.

### BRIEF SUMMARY

In accordance with embodiments of the present invention, a display assembly is provided. The display assembly includes a holder defining a first portion and an electronic device defining a corresponding second portion that is in magnetic attraction to the first portion when the electronic device is positioned about the holder. At least one of the first portion and the second portion defines a magnet having an exposed surface area that increases along a length of the magnet.

In accordance with embodiments of the present invention, a display assembly is provided. The display assembly includes a holder defining a first receiving portion in which a first magnet is defined and an electronic device defining a corresponding portion in which a second magnet is defined. The second magnet is positioned such that the second magnet at least partially overlaps the first magnet when the device is received within the holder. One of the first and second magnets has an exposed surface area that increases along a length thereof.

### BRIEF DESCRIPTION OF THE SEVERAL VIEWS OF THE DRAWINGS

FIG. 1 sets forth a perspective view of a display assembly in which an electronic device is spaced-apart from a holder in accordance with embodiments of the present invention;

FIG. 2 sets forth a perspective view of a display assembly in which the electronic device is spaced-apart from the holder in accordance with embodiments of the present invention;

FIG. 3 sets forth a perspective view of a display assembly in which the electronic device is received within the holder in accordance with embodiments of the present invention;

FIG. 4 sets forth a perspective view of a display assembly in which an electronic device is spaced-apart from a holder in accordance with embodiments of the present invention;

FIG. 5 sets forth an overhead view of a receiving portion of the holder having a magnet assembly therein in accordance with embodiments of the present invention;

FIG. 6A sets forth a perspective view of a display assembly in which the electronic device is received within the holder in a first position in accordance with embodiments of the present invention;

FIG. 6B illustrates a top view of an overlap of a magnet assembly carried by the holder and magnet carried by the electronic device in the position illustrated in FIG. 6A in accordance with embodiments of the present invention;

FIG. 7A sets forth a perspective view of a display assembly in which the electronic device is received within the holder in a second position in accordance with embodiments of the present invention; and

FIG. 7B illustrates a top view of an overlap of a magnet assembly carried by the holder and magnet carried by the electronic device in the position illustrated in FIG. 7A in accordance with embodiments of the present invention.

### DETAILED DESCRIPTION

Exemplary display screen assemblies in accordance with embodiments of the present invention are described herein. Particularly, described herein are exemplary display screen assemblies having a display screen that is selectively engageable about a mount assembly.

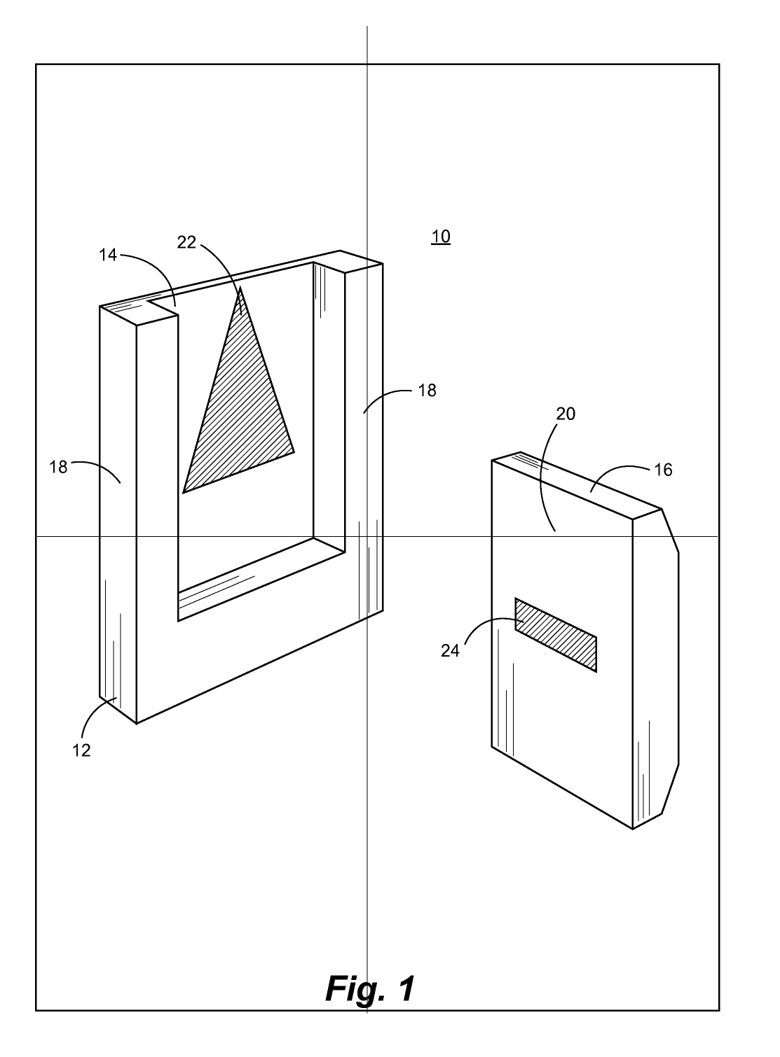

FIG. 1 illustrates a display assembly 10 according to one or more embodiments disclosed herein. The display assembly 10 may be providing for docking or otherwise carrying or displaying an electronic device 16. The electronic device 16 may be any electronic device such as, for example, a portable display device, a display screen, a cellular phone, and the like. The display assembly 10 may include a holder 12 that define a receiving portion 14 between cradle supports 18. The holder 12 may be any appropriate configuration and shape, and may be further secured to, for example, a display stand in a retail setting. The holder 12 may be advantageously provided with input/output (I/O) ports that communicate with the electronic device 16 in order to, for example, supply power thereto.

The electronic device 16 may define a portion 20 that is at least partially in magnetic attraction to the receiving portion 14 when the electronic device 16 is positioned about the holder 12. At least one of the receiving portion 14 and the portion 20 may define a magnet. In the illustrative example shown in FIG. 1, magnet 22 may be provided within the receiving portion 14. Additionally, magnet 24 may be provided about portion 20. In these examples, one of elements 22 and 24 may be a magnet and the other element may be a ferrous or other magnet conducting element. In this manner, when elements 22 and 24 are proximal one another, a magnetic attraction induces magnetic forces on holder 12 and device 16 in order to attract the device 16 into receiving engagement with holder 12.

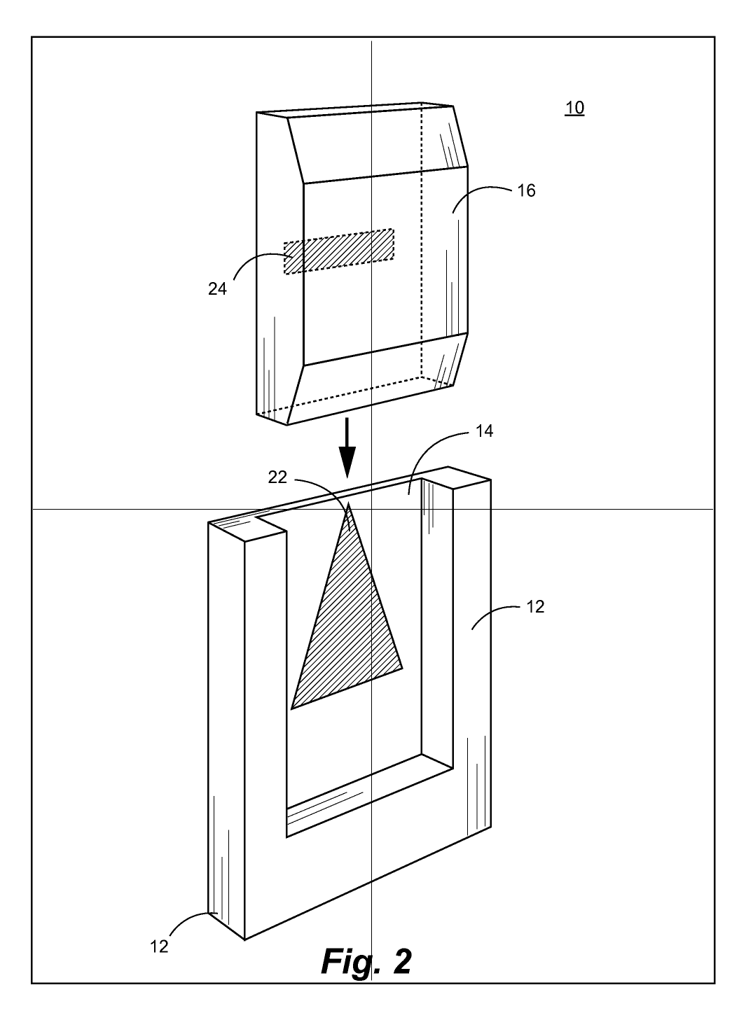

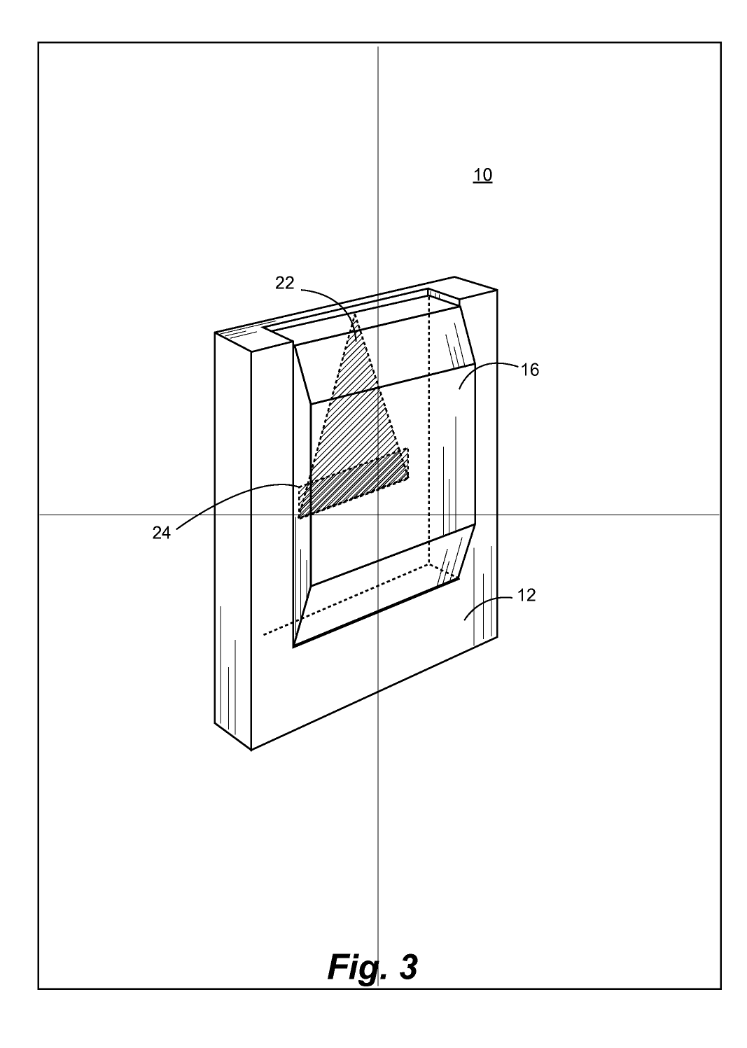

Magnet 22 is illustrated as having a triangle shape in FIG. 1. This advantageously provides for an increased, graduated level of magnetic attraction as device 16 is translated into the holder 12 as illustrated in the sequential views of FIG. 1 and FIG. 2. In the one or more embodiments illustrated in FIGS. 1 through 3, the magnet 22 is configured to define an exposed magnetic surface area that increases along a length thereof. In this manner, the cross-section of magnet 22 increases along a length thereof. With this arrangement, as the electronic device 16 translates downwardly such that element 24, which may be a magnet or ferrous material in these one or more embodiments, and magnet 22 are in magnetic force proximity, the magnetic attraction increases due to the progressively increasing amount of exposed magnetic surface area along of length of magnet 22. As used herein, magnetic force proximity may include magnet to magnet or magnet to ferrous material contact, or may mean a magnet that is spaced-apart from another magnet or ferrous material but still within magnetic force proximity. This advantageously provides for an increased magnetic attraction between holder 12 and device 16 when the device 16 is in the fully docked position, but does not have sufficient magnetic attraction that the device 16 is prematurely or undesirably pulled into holder 12 before being placed there by an operator. This arrangement is provided such that the magnetic forces are strong enough to maintain the device 16 in the docked position until an appropriate amount of external forces, such as a human pulling on device 16, are applied to remove device 16.

Device 16 is mounted within holder 12 by positioning device 16 generally above and aligned with portion 14 as illustrated in FIG. 2. The device 16 is then translated downwardly into holder 12 until the device 16 occupies portion 14. The device 16 is then removed by gripping device 16 and applying sufficient force to overcome the magnetic attraction between magnet 22 and element 24. While device 16 and holder 12 are illustrated in the configurations shown in FIG. 1, each may be of any appropriate configuration.

Element 22 is illustrated as a triangular shape, however, any shape in which the magnetic force emanating from the magnet 22 increases along a length thereof may be appropriate. For example, a rhombus, teardrop shape, or other configuration may be employed. Additionally, element 22 may be provided with greater strength magnetic material along a length thereof to produce the same effect. For example, layering or positioning of a magnetic force of element 22 may be provided by utilizing multiple magnets or magnets of varying magnetic strengths along a dimension thereof. Additionally, element 22 could also be, for example, recessed within a structure where the recess has a varying depth such that the magnetic force emanating therefrom varies along a dimension of the structure. Element 22 may also define a greater depth along a length thereof to produce the graduated magnetic attraction. Element 22 may not have to be a contiguous shape. For example, element 22 may include a plurality of magnets, with the occupied surface area of magnet increasing along the length of element 22. Magnets employed herein may also be advantageously provided as anisotropic magnets, meaning the magnetic force is directional in nature.

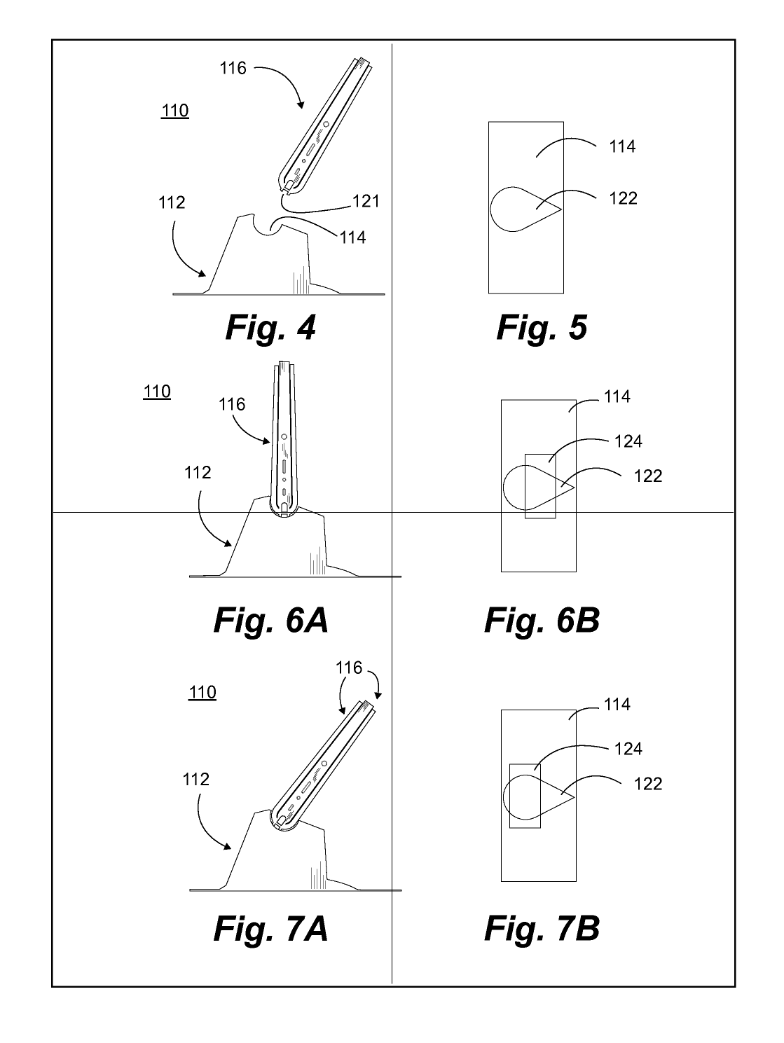

A display assembly 110 according to one or more embodiments is illustrated in FIGS. 4 through 7B. The display assembly 110 includes a holder 112 similar to holder 12 as described with reference to FIGS. 1 through 3. The display assembly 110 also includes an electronic device 116. The electronic device 116 is illustrated as a tablet or laptop, but may be any appropriately configured device. The holder 112 may define a receiving portion 114 that is configured to receive the electronic device 116. The receiving portion 114 is shown having a generally arcuate side section, but may have any appropriate configuration. The receiving portion 114 may include an element 122. Elements 122 may be a magnet in one or more embodiments. Magnet 122 may define a teardrop shape as illustrated in FIG. 5, or may take on any appropriate configuration. Magnet 122 is defined within the receiving portion 114 and has a generally increasing exposed magnet surface about a length of the magnet 122.

The electronic device 116 is illustrated spaced-apart from the holder 112 in FIG. 4. The device 116 is configured to be received in the holder 112 as illustrated in FIG. 6A. In this manner, element 124 is provided proximal magnet 122 and there is a select amount of overlap between element 124 and magnet 122 when device 116 is installed within holder 112. As the electronic device 116 is rotated in the manner illustrated by the directional arrow in FIG. 7A, the overlap between element 124 and magnet 122 increases, thus creating a greater magnetic force attraction between electronic device 116 and holder 112. The device 116 is then removed from holder 112 by rotating the device 116 into the upright position as illustrated in FIG. 6A in order to reduce the magnetic attraction between device 116 and holder 112 so that device 116 may then be lifted upwardly to separate from holder 112. Element 124 is illustrated as a rectangular shape, but may take on any appropriately configured shape, such as, for example, triangular or tear drop shaped.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A display assembly comprising:
a holder defining a first portion;
an electronic device defining a corresponding second portion that is in magnetic attraction to the first portion when the electronic device is positioned about the holder,
wherein at least one of the first portion and the second portion defines a magnet having an exposed surface area that increases along a length of the magnet.

2. The display assembly according to claim 1, wherein each of the first portion and the second portion defines a magnet.

3. The display assembly according to claim 1, wherein the magnet is defined in the first portion.

4. The display assembly according to claim 3, wherein the magnet defines a triangular shape.

5. The display assembly according to claim 3, wherein the magnet defines a rhombus shape.

6. The display assembly according to claim 3, wherein the magnet defines a teardrop shape.

7. The display assembly according to claim 1, wherein the second portion of the electronic device comprises a ferrous material.

8. The display assembly according to claim 1, wherein the second portion comprises a magnetic material.

9. The display assembly according to claim 1, wherein the electronic device is one of a mobile computing device, mobile phone, laptop, and tablet.

10. The display assembly according to claim 1, wherein the holder comprises a cradle having a recess therein that engageably receives the electronic device.

11. The display assembly according to claim 10, wherein the first portion is defined in the recess, and, further wherein, the first portion is a magnet.

12. The display assembly according to claim 1, wherein the holder defines a docking station having an arcuate recess therein that engageably receives the electronic device.

13. A display assembly comprising:
a holder defining a first receiving portion in which a first magnet is defined;
an electronic device defining a corresponding portion in which a second magnet is defined, the second magnet being positioned such that the second magnet at least partially overlaps the first magnet when the device is received within the holder,
wherein one of the first and second magnets has an exposed surface area that increases along a length thereof

14. The display assembly according to claim 13, wherein the first magnet defines a triangular shape.

15. The display assembly according to claim 13, wherein the first magnet defines a rhombus shape.

16. The display assembly according to claim 13, wherein the first magnet defines a teardrop shape.

17. The display assembly according to claim 13, wherein the electronic device is one of a mobile computing device, mobile phone, laptop, and tablet.

18. The display assembly according to claim 13, wherein the holder comprises a cradle having a recess therein that engageably receives the electronic device.

19. The display assembly according to claim 13, wherein the holder defines a docking station having an arcuate recess therein that engageably receives the electronic device.

20. A display assembly comprising:
a holder defining a first receiving portion in which a first magnet is defined;
an electronic device defining a corresponding portion in which a second magnet is defined, the second magnet being positioned such that the second magnet at least partially overlaps the first magnet when the device is received within the holder,
wherein one of the first and second magnets has a magnetic force emanating therefrom that varies along a dimension thereof.
